(19) United States
(12) Patent Application Publication
(10) Pub. No.: US 2022/0115590 A1
(43) Pub. Date: Apr. 14, 2022

(54) LOW-POWER PHASE-CHANGE MEMORY TECHNOLOGY WITH INTERFACIAL THERMOELECTRIC HEATING ENHANCEMENT

(71) Applicant: The Board of Trustees of the Leland Stanford Junior University, Palo Alto, CA (US)

(72) Inventors: Asir Intisar Khan, Stanford, CA (US); Eric Pop, Palo Alto, CA (US); Raisul Islam, Stanford, CA (US); H.-S. Philip Wong, Stanford, CA (US); Kenneth E. Goodson, Portola Valley, CA (US); Mehdi Asheghi, Palo Alto, CA (US); Heungdong Kwon, Stanford, CA (US)

(21) Appl. No.: 17/498,369

(22) Filed: Oct. 11, 2021

Related U.S. Application Data
(60) Provisional application No. 63/089,776, filed on Oct. 9, 2020.

(51) Int. Cl. H01L 45/00; H01L 27/24; H01L 35/16; H01L 35/22

(52) U.S. Cl. CPC H01L 45/126; H01L 27/2463; H01L 35/16; H01L 45/16; H01L 45/06; H01L 45/144; H01L 35/22

(57) ABSTRACT

A low-power phase-change memory (PCM) technology with interfacial thermoelectric heating (TEH) enhancement is provided. Embodiments described herein leverage a substantial, positive thermoelectric coefficient in PCM materials to generate additional heating or cooling at an interface with another material, enabling memory switching with a large reduction in current and power. Interfacial thermoelectric engineering is applied to a PCM cell using a special class of thermoelectric materials with large negative Seebeck coefficients (e.g., bismuth telluride (Bi₂Te₃), lead telluride (PbTe), lanthanum telluride (La₃Te₄), indium selenide (InSe), silicon-germanium (Si_{0.8}Ge_{0.2})) to induce efficient heating at significantly lowered power and current.

### RELATED APPLICATIONS

This application claims the benefit of provisional patent application Ser. No. 63/089,776, filed Oct. 9, 2020, the disclosure of which is hereby incorporated herein by reference in its entirety.

### FIELD OF THE DISCLOSURE

The present disclosure relates to phase-change memory for electronic devices.

### BACKGROUND

Phase-change memory (PCM) technology has already been adopted in commercial products as a promising storage-class memory due to its potential to have switching speed, resistance window, and scalability competitive to dynamic random-access memory (DRAM). This technology also offers nonvolatility (such that a memory state is preserved when power is turned off) and longer write endurance than existing nonvolatile technology, such as flash memory.

Despite its great promise, high switching current density (Jᵣₑₛₑₜ) and switching power (Pᵣₑₛₑₜ) have been a key challenge of PCM, including in emerging applications such as neuromorphic and in-memory computing. In addition, the reset current (Iᵣₑₛₑₜ) of PCM must be provided by selector devices in a memory array. As a result, the selectors need to have larger area, limiting storage density. Hence, reduction of Jᵣₑₛₑₜ is essential for high density data storage.

### SUMMARY

A low-power phase-change memory (PCM) technology with interfacial thermoelectric heating (TEH) enhancement is provided. In PCM, storage of one bit of information is realized by switching between a crystalline phase and an amorphous phase of a material. Heat generated by an electrical current through the device causes this change of phase in the material. In a traditional PCM cell, only resistive Joule heating generated by the applied current is responsible for this switching mechanism. However, embodiments described herein leverage a substantial, positive thermoelectric (Seebeck) coefficient (Sₚ) in PCM materials to generate additional heating or cooling at an interface with another material.

Embodiments described herein provide a novel approach to significantly enhance TEH in the PCM cell, overall enabling memory switching with a large reduction (˜2×) in current and power. Interfacial thermoelectric engineering is applied to the PCM cell using a special class of thermoelectric materials with large negative Seebeck coefficients (e.g., bismuth telluride (Bi₂Te₃), lead telluride (PbTe), lanthanum telluride (La₃Te₄), indium selenide (InSe), silicon-germanium (Si_{0.8i}Ge_{0.2})) to induce efficient heating at significantly lowered power and current. Some embodiments enhance the TEH further by tuning or optimizing the Seebeck coefficients of these materials or compositions through doping and controlling the deposition condition (e.g., deposition temperature, pressure, and method) as well as the thickness and relative concentration of the elements in these compositions.

An exemplary embodiment provides a PCM cell. The PCM cell includes a phase-change layer, a thermoelectric semiconductor layer coupled to the phase-change layer, and a first electrode coupled to the thermoelectric semiconductor layer, wherein the thermoelectric semiconductor layer facilitates thermal heating at an interface with the phase-change layer when a current is applied through the first electrode to change a state of the phase-change layer.

Another exemplary embodiment provides a method for providing a

PCM device. The method includes providing a phase change layer and providing a thermoelectric semiconductor layer adjacent the phase-change layer, wherein the thermoelectric semiconductor layer is configured to induce thermoelectric heating at an interface with the phase-change layer when a current is applied through the PCM device.

Another exemplary embodiment provides a PCM device comprising a plurality of PCM cells. Each PCM cell includes a phase-change layer and a thermoelectric semiconductor layer coupled to the phase-change layer and configured to facilitate thermal heating at an interface with the phase-change layer when a set current is supplied to the PCM cell.

Those skilled in the art will appreciate the scope of the present disclosure and realize additional aspects thereof after reading the following detailed description of the preferred embodiments in association with the accompanying drawing figures.

### BRIEF DSCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic cross-sectional diagram of an exemplary thermoelectric heating (TEH)-engineered phase-change memory (PCM) cell according to embodiments described herein.

FIG. 1B is a schematic cross-sectional diagram of another exemplary PCM cell according to embodiments described herein.

FIG. 2A is a schematic cross-sectional diagram of an exemplary PCM device according to the PCM cell design of FIG. 1A.

FIG. 2B is a cross-sectional scanning electron microscope (SEM) image of the PCM device of FIG. 2A.

FIG. 3A is a graphical representation of resistance (R) as a function of current (I) for multiple devices with ˜150 nm first electrode diameter, showing ˜2× lower reset current (Iᵣₑₛₑₜ) for bismuth telluride (Bi₂Te₃)/germanium antimony tellurium (GST) vs. control GST devices.

FIG. 3B is a graphical representation of resistance (R) as a function of current (I), showing that Iᵣₑₛₑₜ of the Bi₂Te₃/GST device scales with the first electrode diameter (here from ˜100 to ˜300 nm), demonstrating the scalability of this technology.

FIG. 3C is a graphical representation of reset current density for PCM devices with and without a Bi₂Te₃ thermoelectric semiconductor layer.

FIG. 3D is a graphical representation of reset voltage for PCM devices with and without the Bi₂Te₃ thermoelectric semiconductor layer.

FIG. 3E is a graphical representation of reset power for PCM devices with and without the Bi₂Te₃ thermoelectric semiconductor layer.

FIG. 4A is a graphical representation of resistance ratio over a large number of switching cycles.

FIG. 4B is a graphical representation of read resistance as a function of current after many switching cycles.

FIG. 4C is a graphical representation comparing resistance drift of PCM devices with and without the Bi₂Te₃ thermoelectric semiconductor layer.

FIG. 5A is a schematic diagram illustrating normal polarity of the Bi₂Te₃/GST PCM device.

FIG. 5B is a schematic diagram illustrating reverse polarity of the Bi₂Te₃/GST PCM device.

FIG. 5C is a graphical representation of read resistance as a function of current for the Bi₂Te₃/GST device.

FIG. 5D is a graphical representation of resistance as a function of current for Bi₂Te₃/GST devices and GST devices operated in normal polarity (NP) and reverse polarity (RP).

FIG. 6A is a graphical representation of an electro-thermal simulation at the end of a NP reset current pulse with a device with a 4 nm Bi₂Te₃ layer and a 50 nm GST layer.

FIG. 6B is a graphical representation of an electro-thermal simulation at the end of a RP reset current pulse with the device of FIG. 6A.

FIG. 6C is a graphical representation of an electro-thermal simulation at the end of a NP reset current pulse with the device of FIG. 6A assuming no thermoelectric effect in the Bi₂Te₃ layer.

FIG. 6D is a graphical representation of an electro-thermal simulation at the end of a NP reset current pulse with a device with only a 50 nm GST layer.

FIG. 6E is a graphical representation of an electro-thermal simulation at the end of a RP reset current pulse with the device of FIG. 6D.

FIG. 6F is a graphical representation comparing heating power for the device of FIG. 6A with the device of FIG. 6D.

FIG. 7 is a graphical representation of measured current density (Jᵣₑₛₑₜ) as a function of contact area for various PCM technologies.

FIG. 8 is a flow diagram of a process for providing a PCM device.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

A low-power phase-change memory (PCM) technology with interfacial thermoelectric heating (TEH) enhancement is provided. In PCM, storage of one bit of information is realized by switching between a crystalline phase and an amorphous phase of a material. Heat generated by an electrical current through the device causes this change of phase in the material. In a traditional PCM cell, only resistive Joule heating generated by the applied current is responsible for this switching mechanism. However, embodiments described herein leverage a substantial, positive thermoelectric (Seebeck) coefficient (Sₚ) in PCM materials to generate additional heating or cooling at an interface with another material.

Embodiments described herein provide a novel approach to significantly enhance TEH in the PCM cell, overall enabling memory switching with a large reduction (˜2×) in current and power. Interfacial thermoelectric engineering is applied to the PCM cell using a special class of thermoelectric materials with large negative Seebeck coefficients (e.g., bismuth telluride (Bi₂Te₃), lead telluride (PbTe), lanthanum telluride (La₃Te₄), indium selenide (InSe), silicon-germanium (Si_{0.8}Ge_{0.2})) to induce efficient heating at significantly lowered power and current. Some embodiments enhance the TEH further by tuning or optimizing the Seebeck coefficients of these materials or compositions through doping and controlling the deposition condition (e.g., deposition temperature, pressure, and method) as well as the thickness and relative concentration of the elements in these compositions.

I. Introduction

In a PCM cell, data is encoded as the resistance change of a chalcogenide-based phase change material (like germanium antimony telluride (Ge₂Sb₂Te₅ or GST)) contacted by a top and bottom electrode. The PCM material (e.g., GST) can be reversibly transformed between amorphous (high-resistance) and crystalline (low-resistance) states. Transformation from the crystalline phase to the amorphous phase requires a current pulse through the memory cell (e.g., induced at the bottom electrode) to generate enough heat to melt the crystalline GST and then it is quenched rapidly to become amorphous. Reducing the bottom electrode diameter can reduce reset current (Iᵣₑₛₑₜ), but reset current density (Jᵣₑₛₑₜ) does not decrease unless the heating efficiency is improved.

Heating efficiency could be improved through better thermal insulation of the PCM cell, or by improving the heating process itself. Traditionally, the heating process relies primarily on Joule heating in the bottom electrode or the GST, however thermoelectric heating (TEH) could also be introduced, especially because GST itself has a non-negligible, positive Seebeck coefficient (Sₚ). Hence, utilization and enhancement of this TEH effect can decrease the power requirement and current density for PCM switching (e.g., decrease the requirement of large Jᵣₑₛₑₜ).

An exemplary embodiment described below demonstrates a large reduction (˜2×) of Jᵣₑₛₑₜ in mushroom-cell PCM with interfacial TEH using a thin bismuth telluride (Bi₂Te₃) interfacial layer at the bottom electrode interface. Bi₂Te₃ is a thermoelectric material with significant but negative Sₙ, which amplifies the TEH effect at the Bi₂Te₃/GST interface due to the difference in their Seebeck coefficients, thus improving the overall heating efficiency. Polarity-dependent experiments and electro-thermal simulations further confirm the TEH effect arising from interfacial engineering to reduce Jᵣₑₛₑₜ and reset power (Pᵣₑₛₑₜ) at similar voltage, while maintaining scalability with the bottom electrode diameter.

The Bi₂Te₃/GST mushroom-cell devices switch at ˜10 megaamperes per square centimeter (MA/cm²) vs. control GST devices at ˜20 MA/cm² at similar voltage, offering a ˜2× reduction in the reset current density and reset power required. In addition, the current required to reset the Bi₂Te₃/GST PCM devices decreases with decreasing bottom electrode area, demonstrating the scalability of this technology. Measurements of polarity-dependent reset current and power in well-cycled devices confirm the strong thermoelectric heating caused by the Bi₂Te₃ interfacial layer.

While Joule heating is always positive, thermoelectric effect switches polarity as the current direction is reversed, in other words, switching from thermoelectric heating in the forward bias to cooling in reverse bias. When probed in reverse (negative) polarity, Bi₂Te₃/GST devices require ˜2× higher reset current and higher reset voltage compared to normal (positive) polarity operation, revealing the significant and consistent thermoelectric effect at the Bi₂Te₃ (n-type) to GST (p-type) interface in these devices.

The thermoelectric heating effect is amplified at the junction of Bi₂Te₃ and GST due to the difference in their Seebeck coefficient (S). Crystalline GST has a positive |S| ˜40 micro volts per Kelvin (μV/K) to ˜100 μV/K from room temperature to ˜200° C., respectively. On the other hand, Bi₂Te₃ thin film has a large but negative Seebeck coefficient with |S| between 200 μV/K and ˜150 μV/K from room temperature to ˜200° C. Compared to PCM devices with Bi₂Te₃/GST bilayer, control GST devices show only small intrinsic thermoelectric asymmetry effect in terms of current, voltage and power when probed in reverse polarity, further confirming the stronger thermoelectric heating caused by the Bi₂Te₃ layer. The reduction in switching current and power in Bi₂Te₃/GST PCM devices is further confirmed by finite-element simulations.

It should be noted that the Bi₂Te₃ layer is an exemplary embodiment of the present disclosure. There are numerous different materials (e.g., Bi₂Te₃ , PbTe, La₃Te₄, InSe, Si_{0.8}Ge_{0.2}) that could be utilized to further enhance the TEH. The key is for them to be compatible with PCM fabrication and operation, and to possess a large Seebeck coefficient difference with the primary phase-change material used within the PCM (e.g. GST).

This PCM technology having enhanced thermoelectric heating with reduced reset power could be a promising route for high density data storage applications. The switching power could further be reduced by enhancing the thermoelectric heating effect. To this end, material design and parametric optimization (e.g., choice of materials, thickness, stoichiometry) to induce a larger difference in the Seebeck coefficient (hence more thermoelectric heating) at the phase change material interface could be employed. Moreover, this could easily be integrated with existing technologies to realize a further reduction in the reset power. As an example, such thermoelectric heating engineering together with thermal and structural confinement could offer a further significant reduction in switching power when integrated with a confined type PCM cell.

II. PCM Cell Design

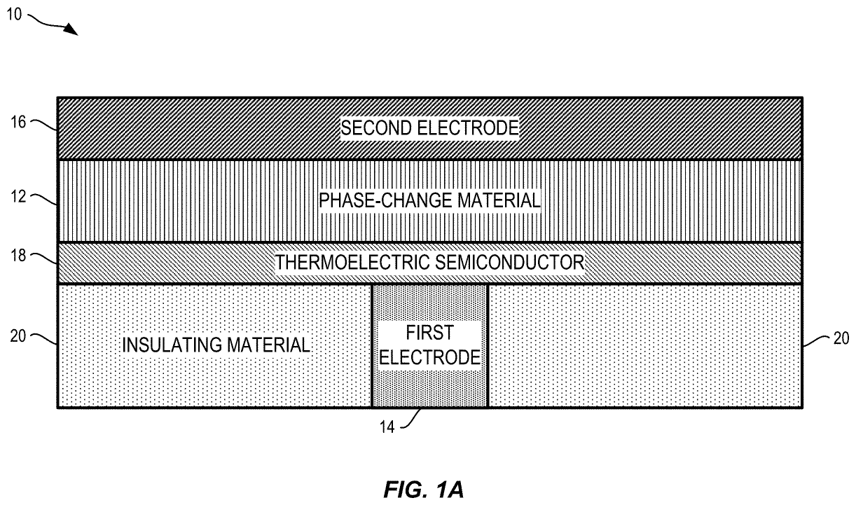

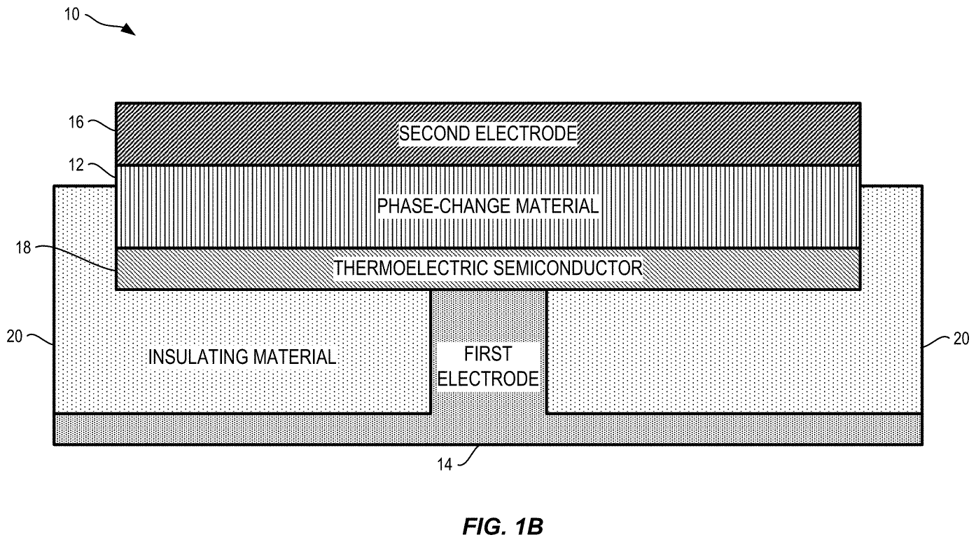

FIG. 1A is a schematic cross-sectional diagram of an exemplary TEH-engineered PCM cell 10 according to embodiments described herein. The PCM cell 10 includes a phase-change layer 12, which can be formed from any appropriate material which reversibly changes state from application of a current through a first electrode 14 (e.g., a bottom electrode) and a second electrode 16 (e.g., a top electrode) across the phase-change layer 12. The state change may correspond to a change in resistance across the phase-change layer 12 induced through heating of the phase-change layer 12 above a threshold temperature. In some examples, the phase-change layer 12 includes a chalcogenide-based phase change material, such as any germanium antimony telluride GeₓSb_{y}Te_{z} material (where x, y, and z indicate any ratio of GST). In some embodiments, the GST or other resistance-based phase change material may include additional dopants and/or may comprise multiple layers of similar or different dopants or materials.

In an exemplary aspect, the PCM cell 10 includes a thermoelectric semiconductor layer 18 which facilitates thermal heating at an interface with the phase-change layer 12. In this regard, the thermoelectric semiconductor layer 18 has a Seebeck coefficient (S) of opposite sign of the phase-change layer 12 such that the thermoelectric heating effect at the interface is amplified due to the difference in their Seebeck coefficients (S). Examples of thermoelectric semiconductor layer 18 materials include one or more of bismuth telluride (Bi₂Te₃ ), lead telluride (PbTe), lanthanum telluride (La₃Te₄), indium selenide (InSe), or silicon-germanium (Si_{0.8}Ge_{0.2}). In some embodiments, the thermoelectric semiconductor layer 18 may represent multiple layers, such as to minimize material mismatch, facilitate greater heating, and/or to improve reliability of the PCM cell 10. In an exemplary aspect, the thermoelectric semiconductor layer 18 material is cross-optimized (e.g., for performance and/or reliability) with the phase-change layer 12 material.

The first electrode 14 and the second electrode 16 may be formed of any appropriate conductive material, such as a metal or highly-conductive semiconductor or composite material. In some embodiments, a diffusion resistance layer, such as a carbon layer, is added at interfaces with the first electrode 14 and/or the second electrode 16, which may improve reliability and endurance of the PCM cell 10.

In an exemplary aspect, performance of the PCM cell 10 is improved by reducing a width of the first electrode 14 relative to the thermoelectric semiconductor layer 18 and the phase-change layer 12. Thus, the first electrode 14 may be disposed through an insulating layer 20, such that the insulating layer 20 is under the thermoelectric semiconductor layer 18 at least partially surrounding the first electrode 14. The insulating layer 20 is generally thermally and electrically insulating, and may be formed from a semiconductor (e.g., low-doped or undoped), dielectric, or other insulating material.

FIG. 1B is a schematic cross-sectional diagram of another exemplary PCM cell 10 according to embodiments described herein. It should be understood that the PCM cell 10 described herein may be configured in a number of different ways. For example, as illustrated in FIG. 1B, the insulating layer 20 may at least partially surround other layers, such as the thermoelectric semiconductor layer 18 and/or the phase-change material 12. In some embodiments, the first electrode 14 may also extend below the insulating layer 20.

With reference to FIGS. 1A and 1B, in some embodiments the first electrode 14 may be considered a bottom electrode which is disposed over a semiconductor substrate or other carrier. In other embodiments, the second electrode 16 may instead be the bottom electrode. In still other embodiments, the layers of the PCM cell 10 may be oriented differently, such as horizontally across a semiconductor substrate.

III. Device Fabrication and Measurement

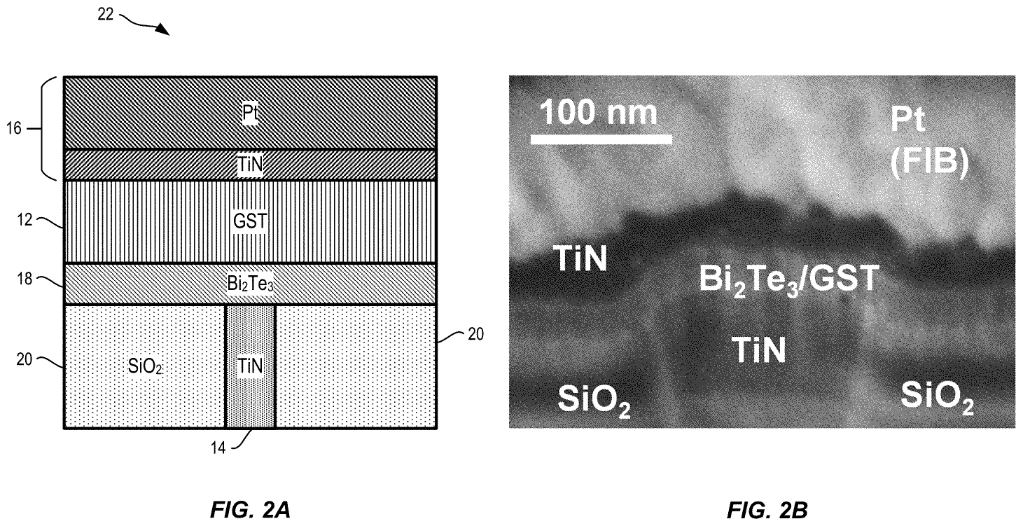

FIG. 2A is a schematic cross-sectional diagram of an exemplary PCM device 22 according to the PCM cell 10 design of FIG. 1A. FIG. 2B is a cross-sectional scanning electron microscope (SEM) image of the PCM device 22 of FIG. 2A. The PCM device 22 in this embodiment is a Bi₂Te₃/GST device with a ˜4 nm thick Bi₂Te₃ thermoelectric semiconductor layer 18 and a ˜50 nm thick GST phase-change layer 12, here on a ˜150 nm diameter titanium nitride (TiN) first electrode 14 (e.g., bottom electrode).

Before sputter depositing ˜4 nm polycrystalline Bi₂Te₃ at room temperature, the first electrode 14 surface was cleaned in situ with argon (Ar) ions to remove native titanium oxide (TiOₓ), then annealed at 180° C. for 30 minutes. A 50 nm GST layer is subsequently sputtered and then ˜10 nm TiN capping layer at room temperature, all without breaking vacuum. Next, the device region is patterned and dry etched followed by fabrication of a second electrode 16 (e.g., top electrode) (TiN/Pt) using sputtering. For set and reset programming, 1/20/300 ns and 1/20/1 ns rise/width/fall pulses are used, respectively. All devices start out in the low-resistance state, indicating good (poly)crystalline quality of the material layers. Unless stated otherwise, all measurements reported here were done after cycling the devices 3000 times to ensure reliable and consistent operation.

IV. Results and Discussion

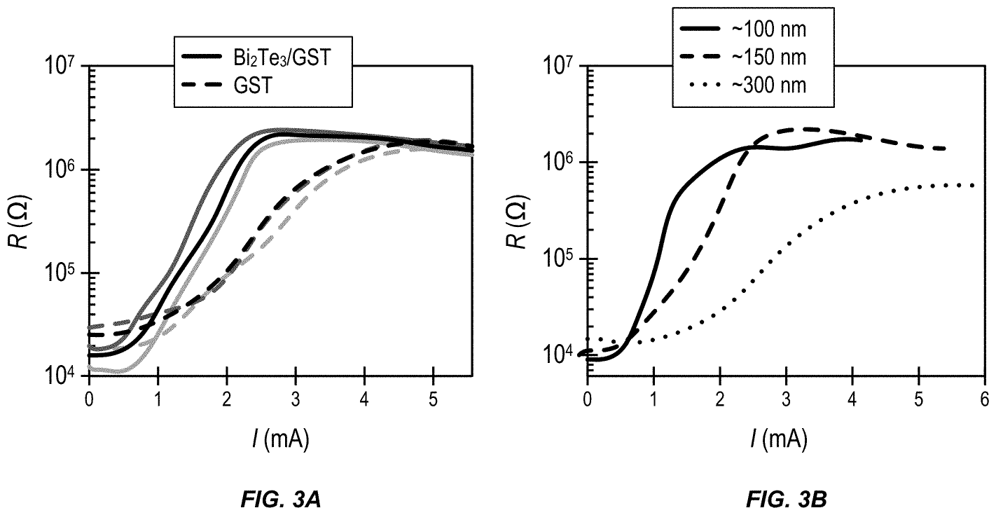

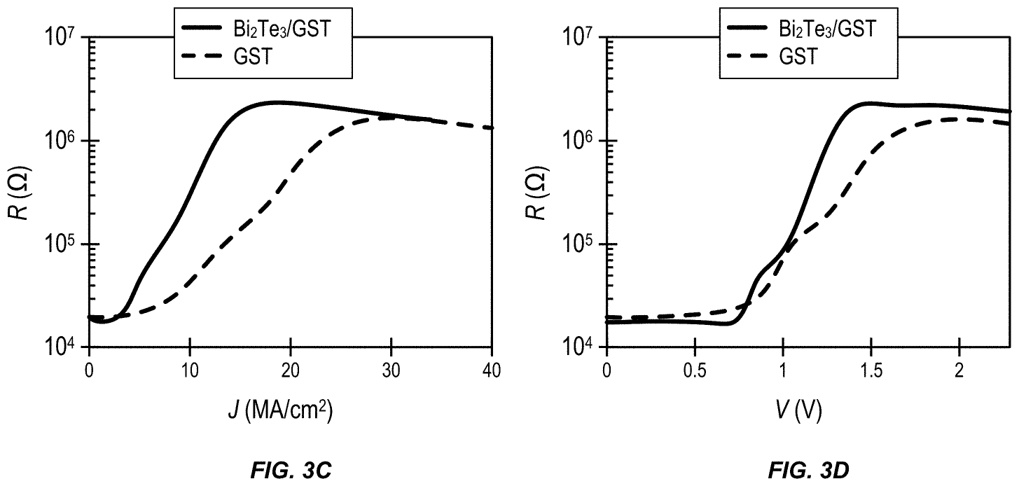

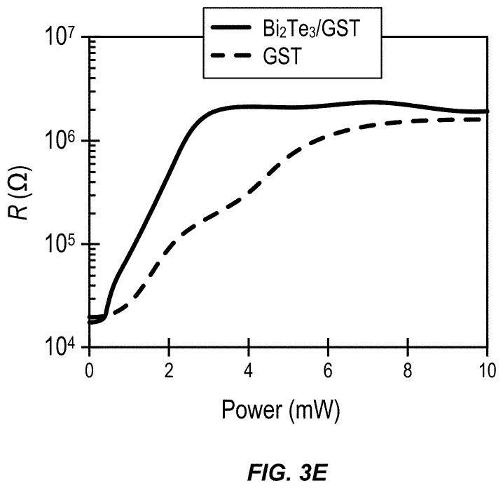

FIG. 3A is a graphical representation of resistance (R) as a function of current (I) for multiple devices with ˜150 nm first electrode 14 diameter, showing ˜2× lower/reset for Bi₂Te₃/GST vs. control GST devices. FIG. 3B is a graphical representation of resistance (R) as a function of current (I), showing that Iᵣₑₛₑₜ of the Bi₂Te₃/GST device scales with the first electrode 14 diameter (here from ˜100 to ˜300 nm), demonstrating the scalability of this technology.

FIG. 3C is a graphical representation of reset current density for PCM devices with and without a Bi₂Te₃ thermoelectric semiconductor layer 18. This reveals that Jᵣₑₛₑₜ for the mushroom-type Bi₂Te₃/GST is ˜10 MA/cm², half that of a control GST device (˜20 MA/cm², typical for GST in this configuration).

FIG. 3D is a graphical representation of reset voltage for PCM devices with and without the Bi₂Te₃ thermoelectric semiconductor layer 18. FIG. 3E is a graphical representation of reset power for PCM devices with and without the Bi₂Te₃ thermoelectric semiconductor layer 18. FIGS. 3D and 3E show that Bi₂Te₃/GST devices switch at similar voltage and thus ˜2× lower reset power (Pᵣₑₛₑₜ) compared to GST control devices.

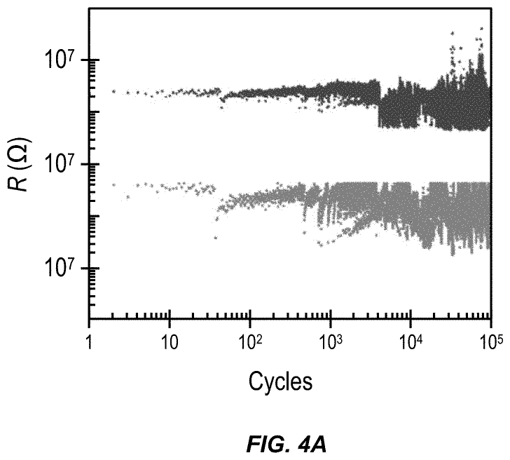

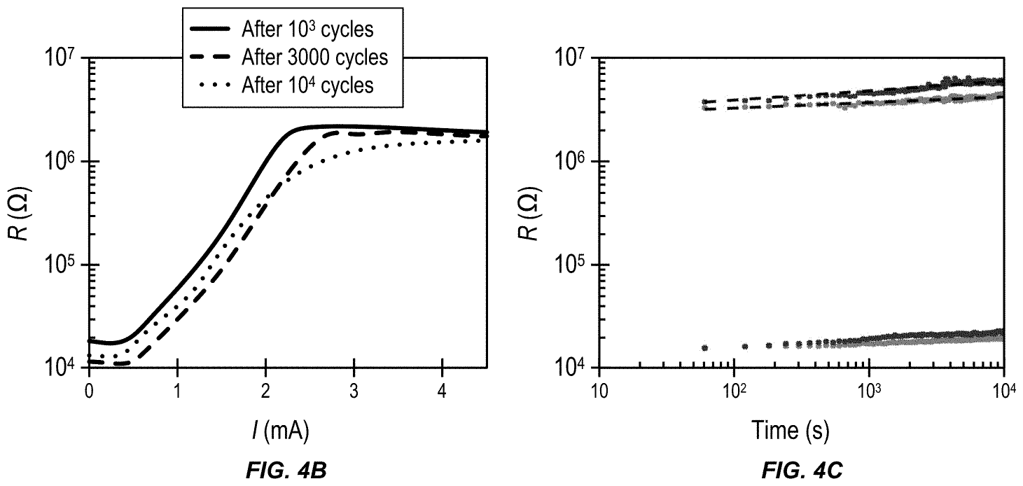

FIG. 4A is a graphical representation of resistance ratio over a large number of switching cycles. This reveals that Bi₂Te₃/GST devices can maintain ≥10× resistance ratio for ≥10⁵ cycles, using a write-verify scheme.

FIG. 4B is a graphical representation of read resistance as a function of current after many switching cycles. This shows the stability of the Bi₂Te₃/GST devices, as the ˜2× reduction Iᵣₑₛₑₜ is maintained even after 10⁴ switching cycles.

FIG. 4C is a graphical representation comparing resistance drift of PCM devices with and without the Bi₂Te₃ thermoelectric semiconductor layer 18. There is ˜40% less resistance drift (v=resistance drift coefficient) compared to control GST PCM devices (shown darker), thereby projecting larger retention in the Bi₂Te₃/GST devices.

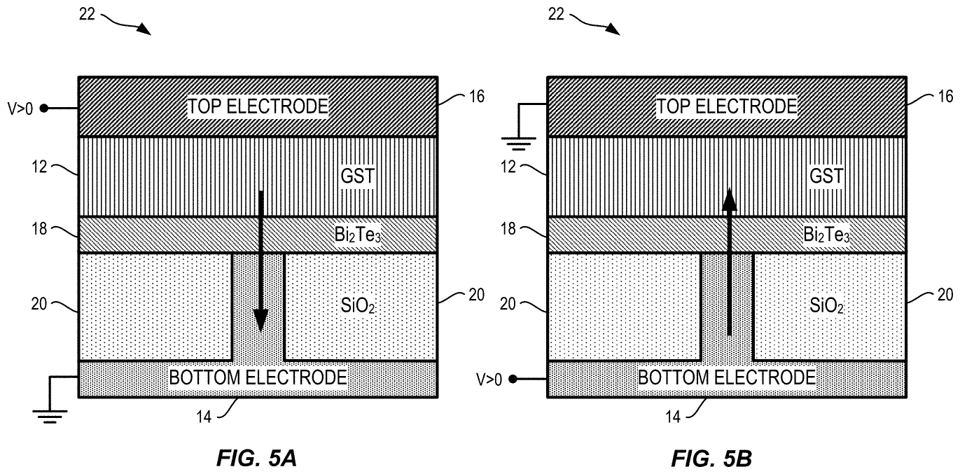

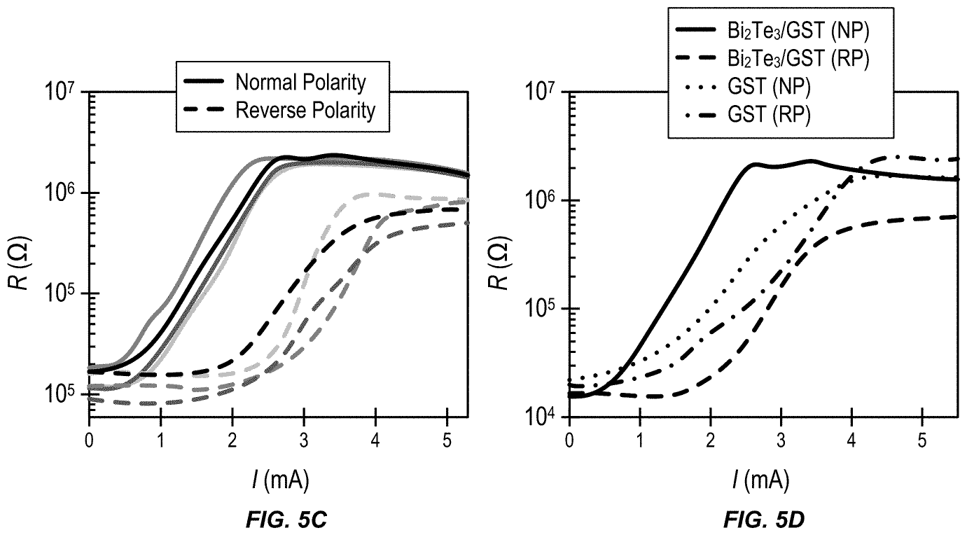

FIG. 5A is a schematic diagram illustrating normal polarity of the Bi₂Te₃/GST PCM device. FIG. 5B is a schematic diagram illustrating reverse polarity of the Bi₂Te₃/GST PCM device. Bias polarity dependent measurements (NP=normal polarity, RP=reverse polarity) are performed with Bi₂Te₃/GST and control GST devices, as shown in FIGS. 5A and 5B. While Joule heating is always positive, the thermoelectric effect is expected to switch sign when the current direction is reversed i.e. from TEH in NP to cooling in RP.

FIG. 5C is a graphical representation of read resistance as a function of current for the Bi₂Te₃/GST device. The Bi₂Te₃/GST devices require ˜2× lower Iᵣₑₛₑₜ in NP vs. RP operation, a direct consequence of the thermoelectric effect at the Bi₂Te₃ (n-type) to GST (p-type) interface in these devices. (n- and p-type polarity of Bi₂Te₃ and GST, respectively, were confirmed by Hall measurements on blanket films.) Crystalline GST has Sₚ>0 (≈−200 μV/K from room temperature to 200° C.), whereas Bi₂Te₃ films have large Sₙ<0 (≈−200 μV/K to −150 μV/K from room temperature to 200° C.). The sign of the Seebeck coefficient indicates whether the charge current flows in the same or opposite direction as the heat carried by holes or electrons, respectively. In addition, it is the difference in Seebeck coefficient (ΔS=Sₚ−Sₙ) which drives an interfacial thermoelectric heating or cooling effect. |Sₙ | is expected to increase for thinner layers like Bi₂Te₃ (˜4 nm here) due to carrier confinement, therefore further enhancing ΔS at the interface.

FIG. 5D is a graphical representation of resistance as a function of current for Bi₂Te₃/GST devices and GST devices operated in NP and RP. In contrast to the Bi₂Te₃/GST device, control GST devices display only small intrinsic asymmetry with respect to the current flow direction, confirming the much larger TEH introduced by the thin Bi₂Te₃ layer in Bi₂Te₃/GST devices. At the same time, the Bi₂Te₃ layer only introduces ˜13% additional thermal resistance in the PCM stack, as shown by separate time domain thermo-reflectance measurements on similar blanket films. In other words, the small additional thermal resistance alone cannot be responsible for the ˜2× change in Jᵣₑₛₑₜ, instead pointing to the key role of TEH at the Bi₂Te₃/GST interface. In addition, the (electrical or thermal) resistance of the Bi₂Te₃ layer cannot account for the asymmetric, polarity-dependent (NP vs. RP) behavior of these devices, which is consistent with a TEH effect.

To gain deeper insight, finite element electro-thermal simulations of the device structures from FIGS. 5A and 5B are performed, including both Joule heating and thermoelectric phenomena. This approach solves the heat equation self-consistently with the current flow, taking advantage of the cylindrical symmetry of the PCM device. The Seebeck heating or cooling is ITΔS at the junction of two materials, e.g. between GST and Bi₂Te₃ , between Bi₂Te₃ and TiN, or between GST and TiN. These simulations also include the T-dependent thermal conductivity, resistivity, and Sₚ of GST, T-dependent Sₙ of Bi₂Te₃ and of TiN, T dependent thermal conductivity and electrical resistivity of TiN and Bi₂Te₃ as well as the measured thermal and thermal boundary resistances at the appropriate interfaces.

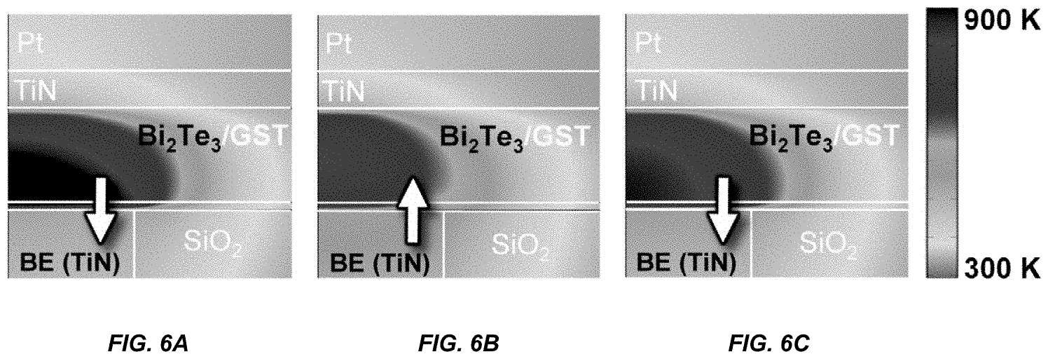

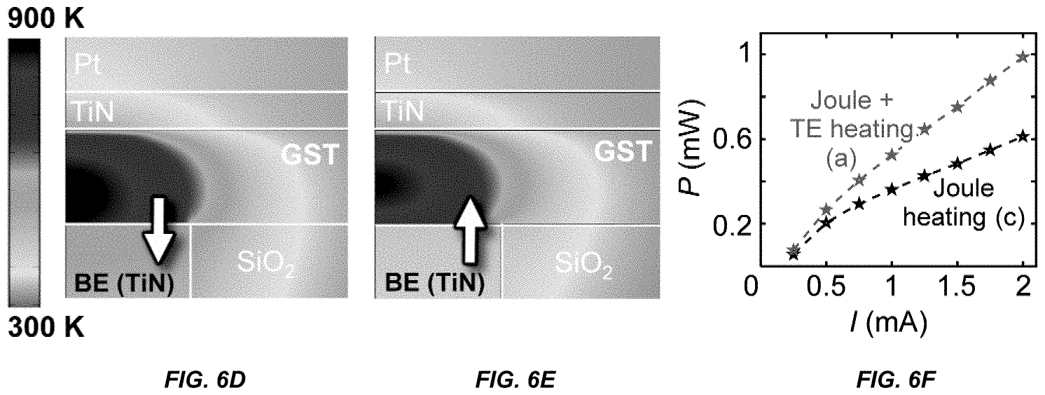

FIG. 6A is a graphical representation of an electro-thermal simulation at the end of a NP reset current pulse with a device with a 4 nm Bi₂Te₃ layer and a 50 nm GST layer. FIG. 6B is a graphical representation of an electro-thermal simulation at the end of a RP reset current pulse with the device of FIG. 6A. FIG. 6C is a graphical representation of an electro-thermal simulation at the end of a NP reset current pulse with the device of FIG. 6A assuming no thermoelectric effect in the Bi₂Te₃ layer. FIG. 6D is a graphical representation of an electro-thermal simulation at the end of a NP reset current pulse with a device with only a 50 nm GST layer. FIG. 6E is a graphical representation of an electro-thermal simulation at the end of a RP reset current pulse with the device of FIG. 6D. For each of these figures, the reset pulse was 2 mA for 20 ns.

In NP operation, the Seebeck effect generates additional TEH, due to the positive ΔS between GST and Bi₂Te₃. This helps the GST reach the melting temperature at lower Iᵣₑₛₑₜ. TEH causes a significantly altered temperature distribution between NP and RP in a Bi₂Te₃/GST device (see FIGS. 6A, 6B) compared to a control PCM device (see FIGS. 6D and 6E). If the thermoelectric effect is ignored in the Bi₂Te₃ layer, the NP temperature profile closely resembles that of the GST-only device, as shown in FIGS. 6C and 6D.

FIG. 6F is a graphical representation comparing heating power for the device of FIG. 6A with the device of FIG. 6D. This comparison reveals TEH adds significantly (˜60%) to the Joule heating component when it is included in simulations.

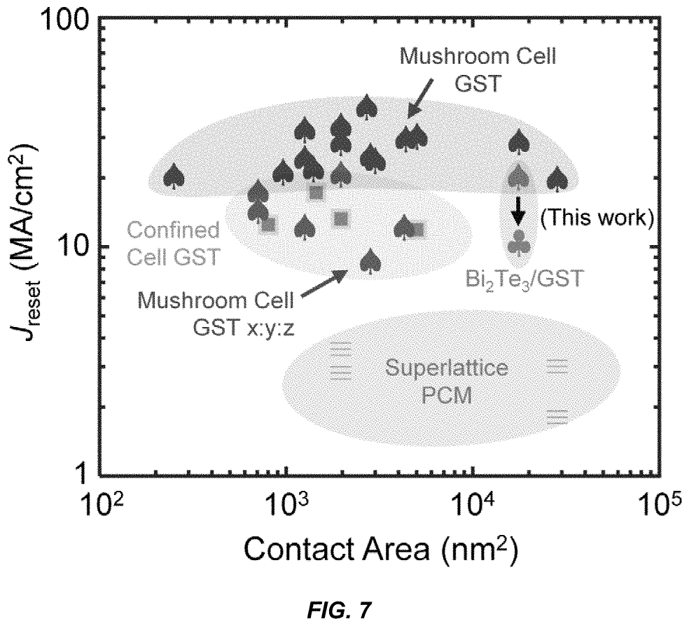

FIG. 7 is a graphical representation of measured current density (Jᵣₑₛₑₜ) as a function of contact area for various PCM technologies. The present PCM technology with enhanced TEH and reduced Pᵣₑₛₑₜ could be promising for high density data storage applications. As shown through benchmarking in FIG. 7, the Bi₂Te₃/GST mushroom PCM cells have ˜2× lower Jᵣₑₛₑₜ (˜10 MA/cm²) compared to similar GST mushroom cells (with 2:2:5 stoichiometry), including control GST devices (˜20 MA/cm²). Lower Jᵣₑₛₑₜ could be achieved with different stoichiometries (x:y:z) or doping of GST in mushroom cells. However, this comes at the expense of higher (10× to 100×) resistivity and switching voltage vs. traditional GST 2:2:5, negating part of the improvement in switching power (Pᵣₑₛₑₜ). In contrast, the Bi₂Te₃/GST cell does not increase the switching voltage and low-resistance state (FIGS. 3A-3E), and the ultrathin Bi₂Te₃ layer could also be combined with other stoichiometries of GST (x:y:z) in the future, if needed.

Lower Jᵣₑₛₑₜ could also be achieved by structural (e.g., pore or edge type geometry) or by electro-thermal confinement in superlattice heterostructures. This, however, often comes with added fabrication complexity and cost. However, some embodiments of the TEH-engineered PCM can be combined with confinement to achieve further Jᵣₑₛₑₜ reduction. This results in −20% further lowering of Jᵣₑₛₑₜ compared to the mushroom cell Bi₂Te₃/GST. Additional reduction in Iᵣₑₛₑₜ and Pᵣₑₛₑₜ could be achieved by optimizing the thermoelectric semiconductor layer 18 with larger negative Sₙ (e.g., Bi₂Te₃ -Sb₂Te₃ alloys with 70% Bi content, Bi-doped SnSe (Sn_{0.94}Bi_{0.06}Se)), enhancing the TEH at the interface with the phase-change layer 12. Further material characterization and imaging of the thermoelectric interface will also provide useful insight into the optimization of such PCM in terms of thermal stability and device failure mechanism.

V. Process for Providing a PCM Device

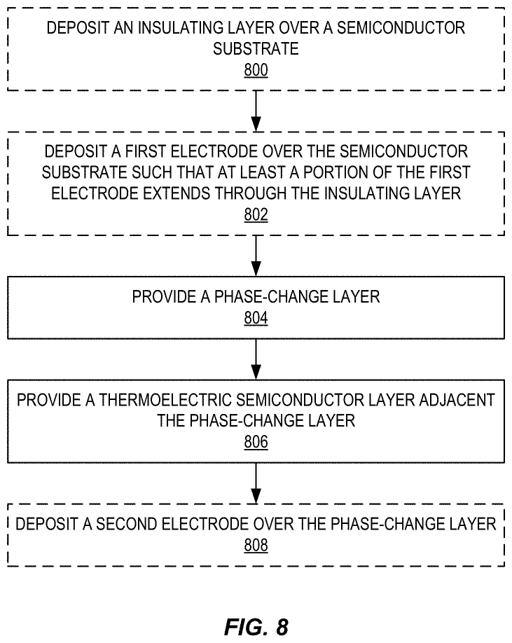

FIG. 8 is a flow diagram of a process for providing a PCM device. Dashed boxes represent optional steps. The process may optionally begin at operation 800, with depositing an insulating layer over a semiconductor substrate. In an exemplary aspect, the semiconductor substrate is a carrier wafer, and a plurality of PCM cells may be formed over the semiconductor substrate, along with a corresponding set of selector devices, to form the PCM device. The process optionally continues at operation 802, with depositing a first electrode over the semiconductor substrate such that at least a portion of the first electrode extends through the insulating layer.

The process continues at operation 804, with providing a phase-change layer. The process continues at operation 806, with providing a thermoelectric semiconductor layer adjacent the phase-change layer. In an exemplary aspect, the thermoelectric semiconductor layer is deposited over the first electrode and the insulating layer, and the phase-change layer is deposited over the thermoelectric semiconductor layer. The process optionally continues at operation 808, with depositing a second electrode over the phase-change layer.

Although the operations of FIG. 8 are illustrated in a series, this is for illustrative purposes and the operations are not necessarily order dependent. Some operations may be performed in a different order than that presented. Further, processes within the scope of this disclosure may include fewer or more steps than those illustrated in FIG. 8.

Those skilled in the art will recognize improvements and modifications to the preferred embodiments of the present disclosure. All such improvements and modifications are considered within the scope of the concepts disclosed herein and the claims that follow.

What is claimed is:

1. A phase-change memory (PCM) cell, comprising:
a phase-change layer;
a thermoelectric semiconductor layer coupled to the phase-change layer; and
a first electrode coupled to the thermoelectric semiconductor layer, wherein the thermoelectric semiconductor layer facilitates thermal heating at an interface with the phase-change layer when a current is applied through the first electrode to change a state of the phase-change layer.

2. The PCM cell of claim 1, further comprising an insulating layer coupled to the thermoelectric semiconductor layer.

3. The PCM cell of claim 2, wherein the first electrode is disposed through the insulating layer.

4. The PCM cell of claim 2, wherein the insulating layer at least partially surrounds the thermoelectric semiconductor layer.

5. The PCM cell of claim 1, further comprising a second electrode coupled to the phase-change layer opposite the interface, wherein the current flows through the first electrode and the second electrode.

6. The PCM cell of claim 1, wherein the thermoelectric semiconductor layer has a Seebeck coefficient of opposite sign of the phase-change layer.

7. The PCM cell of claim 1, wherein a difference in Seebeck coefficients between the thermoelectric semiconductor layer and the phase-change layer induces thermoelectric heating of the phase-change layer when the current is applied through the first electrode.

8. The PCM cell of claim 1, wherein the phase-change layer comprises germanium antimony tellurium (GeₓSb_{y}Te_{z}).

9. The PCM cell of claim 1, wherein the thermoelectric semiconductor layer comprises at least one of bismuth telluride (Bi₂Te₃ ), lead telluride (PbTe), lanthanum telluride (La₃Te₄), indium selenide (InSe), or silicon-germanium (Si_{0.8}Ge_{0.2}).

10. A method for providing a phase-change memory (PCM) device, the method comprising:
providing a phase-change layer; and
providing a thermoelectric semiconductor layer adjacent the phase-change layer, wherein the thermoelectric semiconductor layer is configured to induce thermoelectric heating at an interface with the phase-change layer when a current is applied through the PCM device.

11. The method of claim 10, further comprising depositing an insulating layer over a semiconductor substrate, wherein the thermoelectric semiconductor layer is disposed over the insulating layer.

12. The method of claim 11, further comprising depositing a first electrode over the semiconductor substrate such that at least a portion of the first electrode extends through the insulating layer to contact the thermoelectric semiconductor layer.

13. The method of claim 11, further comprising depositing a second electrode over the phase-change layer, wherein the current is applied to the PCM device through the first electrode and the second electrode.

14. A phase-change memory (PCM) device comprising a plurality of PCM cells, each PCM cell comprising:
a phase-change layer; and
a thermoelectric semiconductor layer coupled to the phase-change layer and configured to facilitate thermal heating at an interface with the phase-change layer when a set current is supplied to the PCM cell.

15. The PCM device of claim 14, further comprising a selector device coupled to the plurality of PCM cells and configured to selectively provide the set current to one or more of the PCM cells.

16. The PCM device of claim 15, wherein the selector device is further configured to selectively provide a reset signal to one or more of the PCM cells.

17. The PCM device of claim 14, wherein the plurality of PCM cells are disposed over a common semiconductor substrate.

18. The PCM device of claim 17, further comprising an insulating layer disposed between the common semiconductor substrate and the thermoelectric semiconductor layer of each of the plurality of PCM cells.

19. The PCM device of claim 14, wherein the thermoelectric semiconductor layer of each of the plurality of PCM cells has a Seebeck coefficient of opposite sign of the phase-change layer.

20. The PCM device of claim 14, wherein for each of the plurality of PCM cells:
the phase-change layer comprises germanium antimony tellurium (GₓS_{y}T_{z}); and
the thermoelectric semiconductor layer comprises at least one of bismuth telluride (Bi₂Te₃ ), lead telluride (PbTe), lanthanum telluride (La₃Te₄), indium selenide (InSe), or silicon-germanium (Si_{0.8}Ge_{0.2}).
